(19) United States
(12) Patent Application Publication
(10) Pub. No.: US 2026/0221080 A1
(43) Pub. Date: Jul. 30, 2026

(54) HIGH RESOLUTION DISPLAY

(71) Applicant: VueReal Inc., Waterloo (CA)

(72) Inventor: Gholamreza CHAJI, Kitchener (CA)

(73) Assignee: VueReal Inc., Waterloo, ON (CA)

(21) Appl. No.: 19/149,128

(22) PCT Filed: Feb. 2, 2024
(86) PCT No.: PCT/IB2024/050986

§ 371 Date: Jul. 18, 2025

Related U.S. Application Data
(60) Provisional application No. 63/482,910, filed on Feb. 2, 2023.

(51) Int. Cl. G09G 3/32; H10H 29/01; H10H 29/14

(52) U.S. Cl. CPC G09G 3/32; H10H 29/011; H10H 29/012; H10H 29/142; G09G 2320/029; G09G 2320/043

(57) ABSTRACT

The present invention discloses a method to fabricate an optoelectronic array. The invention further discloses an optoelectronic array architecture with a shared structure microdevice process. In particular, a row and column structure is presented. Also discussed are functional tuning layers, color conversion layers, for color display or color sensors, and programming control structure.

### CROSS-REFERENCE TO RELATED APPLICATIONS

This application claims the benefit of, and priority to, U.S. Provisional Patent Application No. 63/482,910 filed Feb. 2, 2023, which is hereby incorporated by reference herein in its entirety.

### BACKGROUND AND FIELD OF THE INVENTION

The present disclosure relates generally to optoelectronic arrays that can be a display, sensors or a combination thereafter.

### SUMMARY

The invention relates to a method to fabricate a microdevice array, the method comprising, having alternating sub-pixels with one spare sub-pixel wherein no two adjacent rows or adjacent columns have microdevices with a shared structure in the same pixel position.

The invention relates to a method to fabricate an optoelectronic microdevice array, the method comprising, having four microdevices with a shared structure transferred to optoelectronic arrays, and having functional tuning layers create different functions for each microdevice part, creating different microdevice types.

The invention relates to a method to fabricate an optoelectronic microdevice array, the method comprising, having four microdevices with a shared structure transferred to optoelectronic arrays wherein measuring an optoelectronic layer and identifying defects, a microdevice is covered by a specific functional tuning layer to correct for the defective microdevice.

The invention relates to an optoelectronic array architecture, wherein the array is coupled with power lines at an edge where one power rail has two levels.

### BRIEF DESCRIPTION OF THE DRAWINGS

The foregoing and other advantages of the disclosure will become apparent upon reading the following detailed description and upon reference to the drawings.

FIG. 1A shows an example of alternating sub-pixels with one spare sub-pixel.

FIG. 1B shows another related embodiment where one type of microdevice is transferred with the shared structure between adjacent sub-pixels.

FIG. 1C shows another exemplary embodiment of the above invention. Pixels are arranged in rows and columns.

FIG. 2A shows an optoelectronic array architecture.

FIG. 2B shows a pixel embodiment.

FIG. 2C shows an exemplary operation of the pixel circuit.

FIG. 3A shows exemplary embodiment for multi-microdevice structure where microdevices share a base structure.

FIG. 3B shows the diagonal cross section of the structure.

FIG. 3C shows the shared pad is formed on top of a structure and coupled to the shared structure from the side of the pillar structure.

FIG. 3D shows the pillar structure has an opening in the middle and the shared pad is coupled to the shared structure through the opening.

FIG. 3E, the shared contact is on the other side of the share structure which is opposite to the side where microdevices are formed.

FIG. 4A shows another example of microdevices with shared structure.

FIG. 4B, shows a pillar formed in the corner.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

The following description describes a method to make microdevice optoelectronic arrays. It also discloses an optoelectronic array architecture.

One major challenge with the traditional approach to making microdevice optoelectronic arrays is the cost of microdevices. Conventionally, each sub-pixel has a microdevice. For example, in the case of a full-color display, the red sub-pixel has a red microLED, the green sub-pixel has a green microLED, and the blue sub-pixel has blue microLED. Considering a display may have millions of sub-pixels, the cost of devices can be high. One approach is to reduce the number of sub-pixels. This method can reduce the number of microdevices for one or two types of sub-pixels. However, it can affect the array performance.

One approach is to reduce the size of microdevices, so the cost is reduced per microdevice. The challenge is the performance of the microdevice can get compromised. Moreover, transferring small devices can be a major issue. Furthermore, during the fabrication of microdevices, there is a dead space between each microdevice that cannot be smaller than a few micrometers (~5 micrometers). The cost is mainly dominated by dead spacing at a certain device size.

In one embodiment, the sub-pixels in a display are arranged so that at least two sub-pixels in adjacent pixels with the same microdevice are side by side (direction is not important, it can be top, bottom, left or right or another direction). Here, a microdevice structure for the side-by-side subpixel shares at least one structure between more than one microdevice. The shared structure can be a contact pad, base, common electrode, etc. Therefore, the dead space between more than one microdevice is removed.

For example, using a 6″ wafer, one can make around 340 million microLEDs with 5×10 um2 microLED and 5 μm spacing. The microLED number per wafer increases with the new structure to 570 million.

Furthermore, the reduction of microdevice size has less impact on microdevices that share the functional layers in addition to a common pad.

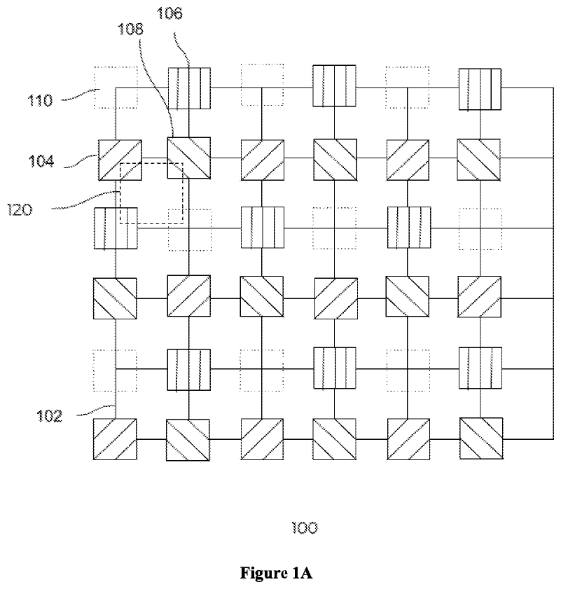

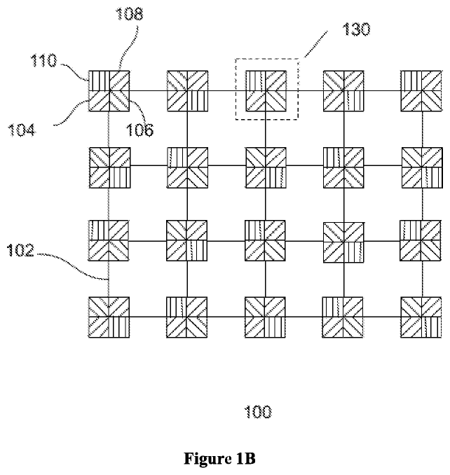

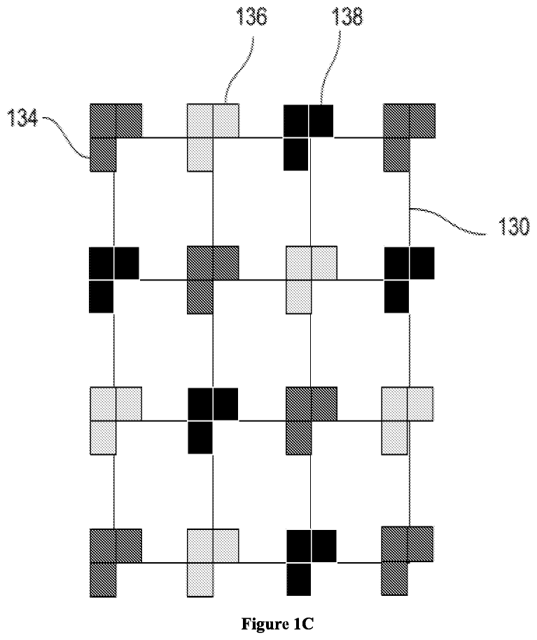

FIG. 1 shows an exemplary optimized optoelectronic array 100 using the shared structure microdevice process. Here the sub-pixels in pixel 102 are arranged so that the subpixel borders three more subpixels with the same microdevice. As a result, the microdevice shares a structure with at least three more microdevices. For example, in the case of full-color displays, the green microdevice covers four adjacent sub-pixels, a red microdevice covers four adjacent subpixels, and a blue microdevice with a shared structure covers another four sub-pixels. To further improve the spatial resolution, the sub-pixels can be alternated.

FIG. 1A shows an example of alternating sub-pixels with one spare sub-pixel 110. Here, no two adjacent rows or adjacent columns have microdevices with the shared structure in the same pixel position. For example, microdevice type 1, 106 and spare sub-pixels 110 alternate their position in the pixels in every other row (or column). Also, microdevices type 2, 104 and type 3, 108 alternate their positions in the pixels in every other row (or column).

The optoelectronic array can be measured after fabrication to determine the defects; the spare sub-pixel can be populated with a microdevice type that matches the defective microdevices in the pixel. In another related embodiment, the spare sub-pixel can be populated with pre-defined microdevices and used to compensate for the defects by turning the spare sub-pixel to replace the defective sub-pixels. Spare sub-pixels may use similar microdevices with shared structures or individual microdevices. A color mixing layer 120 can be added to merge the impact of shared microdevices for each pixel and reduce the effect of sub-pixel rendering.

In another related embodiment, one type of microdevice is transferred with the shared structure between adjacent sub-pixels. Then functional tuning material is used to adjust the function of each microdevice. For example, the color conversion layer can adjust the function of each microdevice accordingly.

FIG. 1B shows an exemplary embodiment of the above invention. The four microdevices 130 with a shared structure are transferred to optoelectronic arrays. The functional tuning layers create different functions for each microdevice part, creating different microdevice types 104, 106, 108, and 110. Two microdevices can have similar functional tuning layers 104, 108. In another case, a microdevice layer is not covered with any functional tuning layer. After measuring the optoelectronic layer and identifying the defects, the microdevice can be covered by a specific functional tuning layer to correct for the defective microdevices. In another embodiment, the pattern of the functional tuning layer is not the same for two adjacent rows or columns. In the case presented in FIG. 1B, the functional tuning layers 106 and 108 are rotating. In one related embodiment, the pixel is formed by one set of four microdevices with a shared structure. In another related embodiment, the pixel is formed by four adjacent microdevices with shared structures. For example, if the optoelectronic array is a color display (or color image sensor), functional tuning layers 104 and 110 can be color green color conversion layers; functional layers 106 is for blue, and layer 110 is for red. Blue can be a color conversion layer or a transparent layer (or no layer) for passing the microLED native blue color. In one related embodiment, 104 can be green, and 108 can be another color, such as light blue, orange or so on.

FIG. 1C shows another exemplary embodiment of the above invention. Pixels 130 are arranged in rows and columns. Different microdevices 134, 136 and 138 with shared structures are transferred into the pixels 130 in diagonal arrangement so that there are no similar microdevices 134, 136 and 138 in adjacent pixels in the row or column.

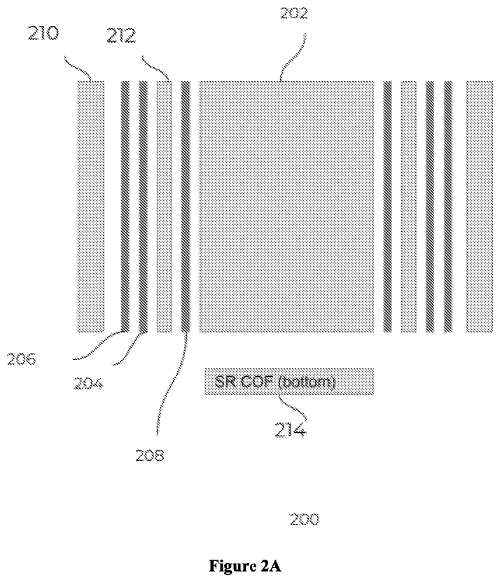

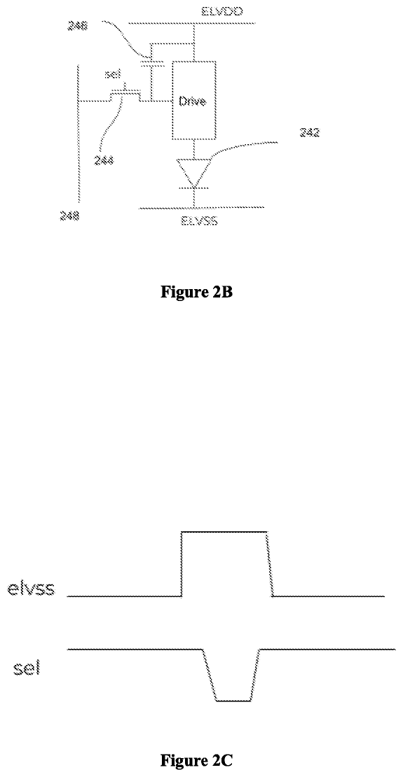

Another challenge with high resolution is fitting the pixel circuits in a given pixel space. FIG. 2 shows the embodiment that some of the elements of the pixels are shared between rows at the edge of the display. In a related embodiment, the pixel circuit is shared between a couple of microdevices in a pixel or adjacent pixel.

FIG. 2A shows the optoelectronic array architecture 200. The array 202 is coupled with power lines 204, 206 208 at the edge where one of the power rails has two levels (lines), 204 and 206. An address block 212 can be used to enable the programming of each row. Here data/column lines are connected to the internal storage of a pixel circuit through a switch controlled by the address block 212. A data driver 214 connected to the column line adjusts the bias level of the column line based on the connected pixels connected to the column lines. After the programming cycle, address block 212 disconnects the column line from the storage element in the pixel by turning off the switch. The pixel circuit drives the microdevices by a value corresponding to the programming bias level. The power rails are distributed in rows to provide for better programming and driving of the pixels in one row.

During the frame time, each row can go through a different status. For example, it can be set so that each pixel stores the programming bias (programming cycle), it can be set so each pixel drives the microdevice associated with the pixel. Here, depending on the row's status, either power level is connected to the associated power rail. For example, during the programming, level one 204 can be applied to the power rails allowing certain functions at the pixel circuits to minimize the voltage drop impact. During the driving cycle, another level 206 is applied to the rail allowing the pixel circuits to drive the microdevices. An address block 210 can be used to control the power level switching for one of the power rails. The two address blocks for the power rail and programming 210 212 can be the same. The address blocks and power rails can be on one side or two sides of array 202. In one case, one side controls the odd rows and the other side even rows or other combinations thereafter.

FIG. 2B shows a pixel embodiment allowing the functionality described above. Here, the power rail with a two-level is an ELVSS directly connected to the microdevice 242 (it can be easily switched to ELVDD).

Switch 244 controls the programming of bias level to storage element 246. The SEL signal is generated by the programming address block.

FIG. 2C shows an exemplary operation of the pixel circuit. Here, the SEL is enabled to allow column line 248 to get connected to storage element 246. ELVSS is connected to second bias level 206, so the microdevice 242 is off. Since no current passes through the drive element, there is no bias drop across ELVDD (it is distributed in rows and all pixels in that row are off due to the ELVSS bias level). As a result, the voltage stored in storage element 244 is not affected by bias drop. During driving, the ELVSS voltage goes to the first level 204 allowing the drive element to control the current of the microdevice based on the voltage stored in the storage element.

In one related embodiment, the pixel circuit is connected to two adjacent microdevices in two adjacent rows. During the first subframe, one of the microdevices is enabled while the ELVSS of one microdevice is connected to bias voltage two (the microdevice is off). During the second subframe, the other microdevice is enabled while the ELVSS of the first microdevice is connected to level 2 (the microdevice is off).

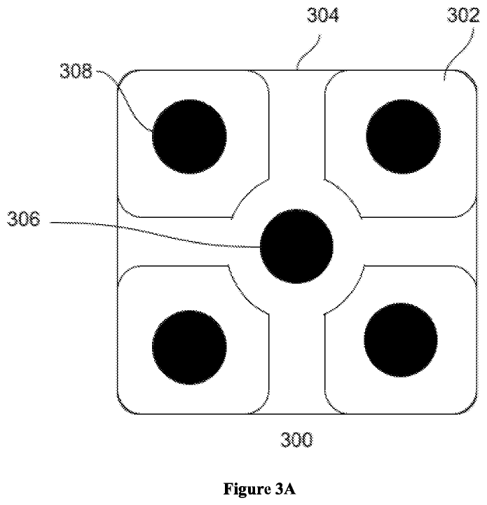

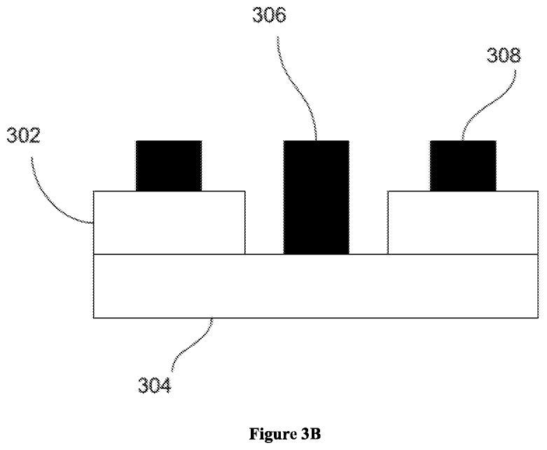

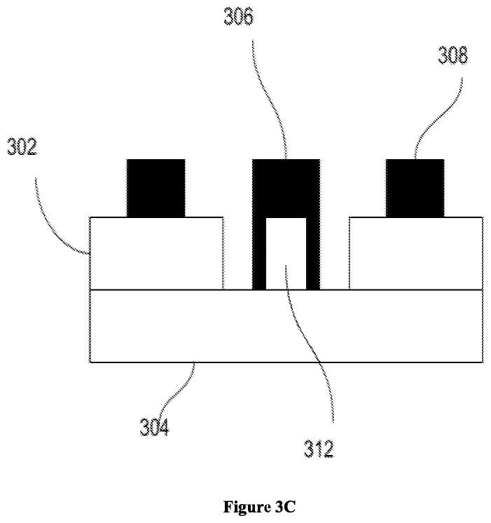

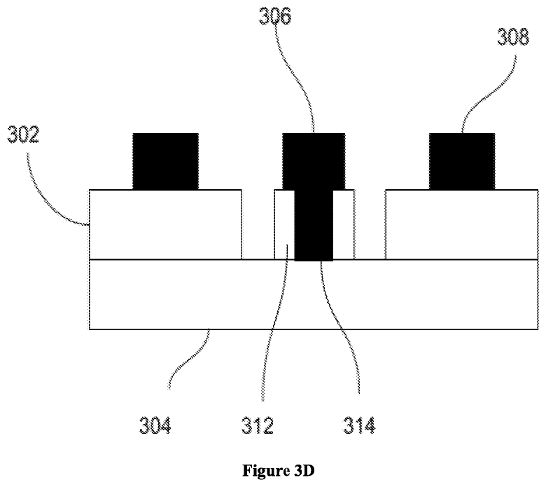

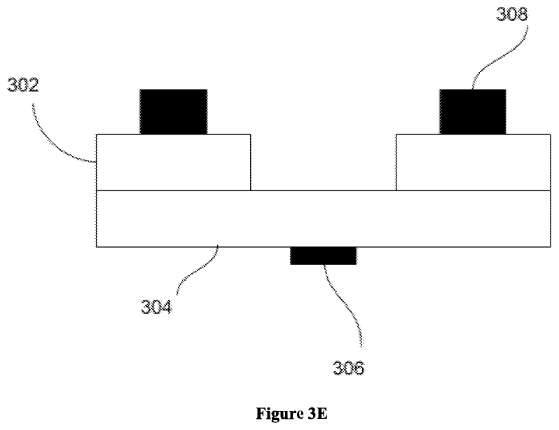

FIG. 3A shows exemplary embodiment for multi-microdevice structure 300 where microdevices 302 share a base structure 304. Each microdevice has individual contact 308. There is a shared contact 306 that can be coupled to the shared base 305. The microdevices 308 can be separated by physical trenches between them. In another related embodiment the devices are separated by modifying the property of the layers between the devices. The microdevice may have an ohmic layer, blocking layer, or active layers. And the shared structure may have blocking layer, ohmic layer, buffer layers or more. The active layers can be quantum wells. In one related embodiment, a dielectric layer can cover the devices' surfaces or sidewalls. In order to connect the contact 308 or 306 to the layers, the dielectric is opened.

FIG. 3B shows the diagonal cross section of the structure. In this structure, the shared contact 306 is coupled to the shared base 304 and the microdevices are formed around the shared contact 306 and each microdevice has a separate contact 308.

In another related embodiment, depicted in FIG. 3C, the shared pad 306 is formed on top of a structure 312 and coupled to the shared structure 304 from the side of the pillar structure 312. The pillar structure 312 can be the same layers as the microdevice layers 302 and formed at the same time as the microdevice 302 are formed.

In another related embodiment shown in FIG. 3D, the pillar structure 312 has an opening in the middle 314 and the shared pad 308 is coupled to the shared structure 304 through the opening 314.

In another related embodiment in FIG. 3E, the shared contact 306 is on the other side of the share structure 304 which is opposite to the side where microdevices 302 are formed.

One method of fabricating devices demonstrated in FIG. 3 are as follows. A substrate is provided, a cleaning process may be done. The cleaning process can be chemical or plasma treatment. Stacks of layers are deposited on the substrate. The layers include the layers needed for shared structure and microdevice structure. After that, annealing process may be carried out, ohmic layers may get formed and annealed. The microdevice structures are formed from the deposited layers. This process may include forming masks and etching microdevice layers from the unwanted areas till it reaches the shared structure surface. Here, one can treat the sidewalls chemically or with other means and deposit passivation layers. The passivation layers can be dielectric such as atomic layer deposition (ALD) or PECVD deposited dielectric. The shared structure can be isolated for the devices that are not sharing a similar structure. contacts are formed after opening the dielectric layers.

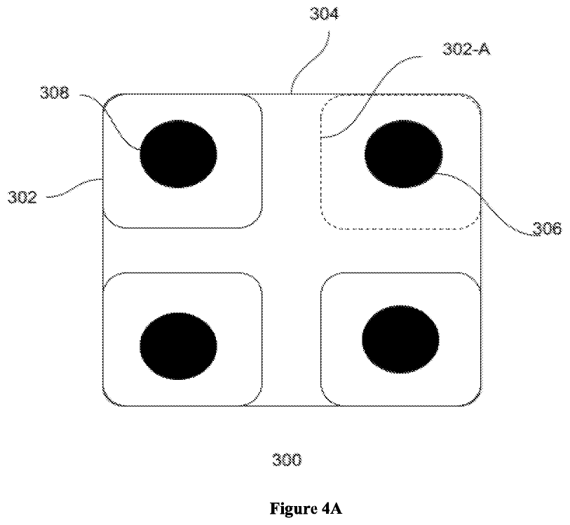

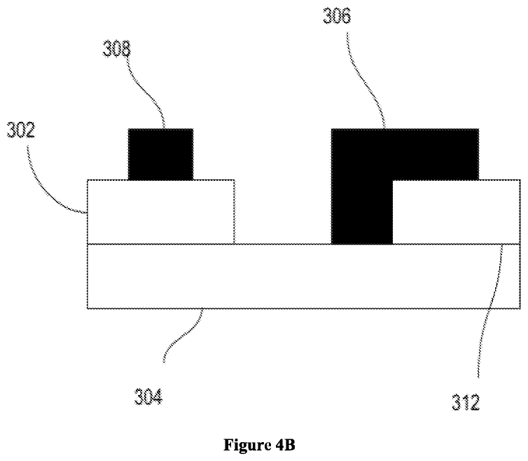

FIG. 4A shows another example of microdevices 302 with shared structure 304. Here, three positions are used to develop microdevices and the fourth corner 302-A is used for the shared contact 306.

In one embodiment shown in FIG. 4B, the pillar 312 is formed in the corner 302. And the shared contact 306 is coupled to the shared structure from the side of pillar 312.

One method of fabricating devices demonstrated in FIG. 4 are as follows. A substrate is provided, a cleaning process may be done. The cleaning process can be chemical or plasma treatment. Stacks of layers are deposited on the substrate. The layers include the layers needed for shared structure and microdevice structure. After that, annealing process may be carried out, ohmic layers may get formed and annealed. The microdevice structures are formed from the deposited layers. This process may include forming masks and etching microdevice layers from the unwanted areas till it reaches the shared structure surface. Here, one can treat the sidewalls chemically or with other means and deposit passivation layers. The passivation layers can be dielectric such as atomic layer deposition (ALD) or PECVD deposited dielectric. The shared structure can be isolated for the devices that are not sharing a similar structure. contacts are formed after opening the dielectric layers.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method to fabricate a microdevice array, the method comprising:
having alternating sub-pixels with one spare sub-pixel wherein no two adjacent rows or adjacent columns have microdevices with a shared structure in a same pixel position.

2. The method of claim 1, wherein the spare sub-pixel is populated with a microdevice type that matches defective microdevices in the pixel.

3. The method of claim 1, wherein the spare sub-pixel is populated with pre-defined microdevices and compensate for defects by turning the spare sub-pixel to replace defective sub-pixels.

4. The method of claim 3, wherein the pare sub-pixels may use similar microdevices with shared structures or individual microdevices.

5. The method of claim 4, wherein a color mixing layer is added to merge an impact of shared microdevices for each pixel and reduce an effect of sub-pixel rendering.

6. The method of claim 5, wherein one type of microdevice is transferred with the shared structure between adjacent sub-pixels and a functional tuning material is used to adjust a function of each microdevice.

7. The method of claim 6, wherein a color mixing layer can adjust the function of each microdevice accordingly.

8. A method to fabricate an optoelectronic microdevice array, the method comprising:
having four microdevices with a shared structure transferred to optoelectronic arrays; and
having functional tuning layers create different functions for each microdevice part, creating different microdevice types.

9. The method of claim 8, wherein two microdevices have similar functional tuning layers.

10. A method to fabricate an optoelectronic microdevice array, the method comprising:
having four microdevices with a shared structure transferred to optoelectronic arrays; and
measuring an optoelectronic layer and identifying defects, a microdevice is covered by a specific functional tuning layer to correct for the defective microdevice.

11. The method of claim 10, wherein a pattern of the functional tuning layer is not the same for two adjacent rows or columns.

12. The method of claim 10, wherein two adjacent functional tuning layers are rotating.

13. The method of claim 10, wherein the pixel is formed by one set of four microdevices with the shared structure.

14. The method of claim 10, wherein the pixel is formed by four adjacent microdevices with shared structures.

15. The method of claim 11, wherein the optoelectronic array is a color display or a color sensor, with functional tuning layers being color green color conversion layers, functional layers for blue, and another layer for red.

16. The method of claim 10, wherein pixels are arranged in rows and columns and different microdevices wherein further different microdevices with shared structures are transferred into the pixels in a diagonal arrangement with no similar microdevices in adjacent pixels in the row or the column.

17. The method of claim 15, wherein blue is a color conversion layer or a transparent layer (or no layer) for passing a microLED native blue color.

18-29. (canceled)
